(19) United States
(12) Patent Application Publication
(10) Pub. No.: US 2013/0260532 A1
(43) Pub. Date: Oct. 3, 2013

(54) Method for Manufacturing Semiconductor Device

(71) Applicants: Haizhou Yin, Poughkeepsie, NY (US); Wei Jiang, Beijing (CN)

(72) Inventors: Haizhou Yin, Poughkeepsie, NY (US); Wei Jiang, Beijing (CN)

(21) Appl. No.: 13/512,331

(22) PCT Filed: Apr. 9, 2012
(86) PCT No.: PCT/CN12/00466

§ 371 Date: May 26, 2012

(30) Foreign Application Priority Data
Mar. 29, 2012 (CN) 201210088443.1
Apr. 9, 2012 (CN) PCT/CN2012/000466

(51) Int. Cl. H01L 21/762

(52) U.S. Cl. 438/430; 257/E21.547

(57) ABSTRACT

The present invention discloses a method for manufacturing a semiconductor device, comprising: forming a shallow trench in a substrate; forming a shallow trench filling layer in the shallow trench; forming a cap layer on the shallow trench filling layer; and implanting ions into the shallow trench filling layer and performing an annealing to form a shallow trench isolation. In the method for manufacturing the semiconductor device according to the present invention, an insulating material is formed by implanting ions into the filling material in the shallow trench, and a compressive stress is applied to the active region of the substrate due to the volume expansion of the filling material, so that the carrier mobility in the channel regions to be formed later can be increased and the device performance can be improved.

### CROSS-REFERENCE TO RELATED APPLICATION

This application is a National Stage application of, and claims priority to, PCT Application No. PCT/CN2012/000466, filed on Apr. 9, 2012, entitled “Method for Manufacturing Semiconductor Device”, which claimed priority to Chinese Application No. 201210088443.1, filed on Mar. 29, 2012. Both the PCT Application and Chinese Application are incorporated herein by reference in their entireties.

### FIELD OF THE INVENTION

The present invention relates to a method for manufacturing a semiconductor device, and in particular, to a method for manufacturing a shallow trench that introduces a stress into the STI by implanting oxygen.

### BACKGROUND OF THE INVENTION

Ever since the 90 nm CMOS integrated circuit technology, with the continuous reduction in the feature size of the device, the Strain Channel Engineering for the purpose of increasing the carrier mobility in the channel region is playing a more important role continuously. The carrier mobility can be effectively increased by introducing a stress into the channel region using a technology, so that the driving capability of the device can be enhanced.

As shown in Table 1 below, many researches have proved that there is a great difference between the piezoresistance coefficients of the NMOS and PMOS devices having channel regions with <110> crystal orientation on a (001) wafer, wherein the unit of the piezoresistance coefficient is 10⁻¹² cm²/dyn.

| (001) wafer | <100> | <100> | <110> | <110> |
|---|---|---|---|---|
| polarity | π∥ | π⊥ | π∥ | π⊥ |
| | π₁₁ | π₁₂ | (π₁₁ + π₁₂ + | (π₁₁ + π₁₂ − |
| | | | π₄₄)/2 | π₄₄)/2 |
| n-MOSFET | −42.6/−102 | −20.7/53.4 | −35.5/−31.6 | −14.5/−17.6 |
| p-MOSFET | 9.1/6.6 | −6.2/−1.1 | 71.7/71.8 | −33.8/−66.3 |

It can be seen that, in the direction of the length of the channel, i.e. in the direction of the vertical axis, it exhibits that the PMOS device has a higher compressive stress when the channel direction is <110> direction on the (001) wafer. Therefore, the NMOS and PMOS devices can theoretically be manufactured by forming active regions (well regions) with different crystal orientations on the (001) wafer substrate, respectively, so that each of the MOSFETs has either a tensile stress or a compressive stress, thereby effectively increasing the carrier mobility. However, such a method requires extra complicated processes, for example, epitaxying active regions and well regions with different crystal orientations on the substrate, respectively, which prolong the process time and increase the manufacturing cost.

Another solution that is theoretically feasible is to apply a stress to the channel region by means of a stress occurring at the contact interface between different materials, especially materials with different crystal structures. As an example, a compressive stress and a tensile stress are caused by a mismatch between the crystal lattices of the substrate Si and the source region SiGe and between the crystal lattices of the substrate Si and the drain region SiC, respectively, which applies to the PMOS and NMOS devices. Likewise, in this solution, extra steps of etching the substrate to form trenches and performing epitaxial growth are required, which results in high cost.

In summary, the existing methods for introducing a stress into the channel region may result in a complicated process and high cost.

### SUMMARY OF THE INVENTION

In view of the above, an object of the present invention is to provide a method for manufacturing a shallow trench isolation that can introduce a stress into the channel region easily and inexpensively.

To achieve the above object, the present invention provides a method for manufacturing a semiconductor device, comprising: forming a shallow trench in a substrate; forming a shallow trench filling layer in the shallow trench; forming a cap layer on the shallow trench filling layer; and implanting ions into the shallow trench filling layer and performing an annealing to form a shallow trench isolation.

Preferably, after forming the shallow trench and before forming the shallow trench filling layer, the method further comprises forming a liner in the shallow trench.

Preferably, forming the shallow trench further comprises: forming a hard mask layer on the substrate; photoetching/etching the hard mask layer to form a hard mask layer pattern which has a plurality of openings exposing the substrate; and etching the substrate exposed in the openings to form the shallow trench.

Preferably, forming the shallow trench filling layer further comprises: depositing a shallow trench filling layer in the shallow trench; planarizing the shallow trench filling layer to expose the hard mask layer; and etching the shallow trench filling layer so that the upper surface of the shallow trench filling layer is lower than the upper surface of the hard mask layer.

Preferably, the hard mask layer includes at least a first hard mask layer and a second hard mask layer. The shallow trench filling layer is etched so that the upper surface of the shallow trench filling layer is lower than the upper surface of the first hard mask layer.

Preferably, the liner and/or cap layer comprise one of nitrides and oxynitrides.

Preferably, the thickness of the cap layer is about 10-20 mm

Preferably, the implanted ions include at least oxygen. Preferably, the implanted ions further include one of N, C, F, B, P, Ti, Ta, and Hf.

Preferably, the dose of the implanted ions is greater than or equal to about 10¹⁶ cm⁻².

Preferably, the shallow trench filling layer comprises one of polysilicon, amorphous silicon, and microcrystal silicon.

In the method for manufacturing the semiconductor device according to the present invention, an insulating material is formed by implanting ions into the filling material in the shallow trench, and a compressive stress is applied to the active region of the substrate due to the volume expansion of the filling material, so that the carrier mobility in the channel regions to be formed later can be increased and the device performance can be improved.

### BRIEF DESCRIPTION OF THE DRAWINGS

The technical solutions of the present invention will be described in detail below with reference to the accompanying drawings, wherein:

FIGS. 1-6 are schematic cross-sectional views of the various steps of a method for manufacturing a semiconductor device according to the present invention.

### DETAILED DESCRIPTION OF THE PREFERRED EMBODIMENTS

The features and technical effects of the technical solutions of the present invention will be described in detail below with reference to the drawings and in combination with exemplary embodiments. A method for manufacturing a shallow trench isolation that can introduce a stress into the channel region easily and inexpensively is disclosed. It shall be noted that like reference signs denote like structures, and the terms used in the present invention, such as “first”, “second”, “above”, “below”, and the like, can be used to modify various device structures or manufacturing processes. Unless specified otherwise, such modification does not imply the spatial, sequential or hierarchical relationships between the device structures or manufacturing processes.

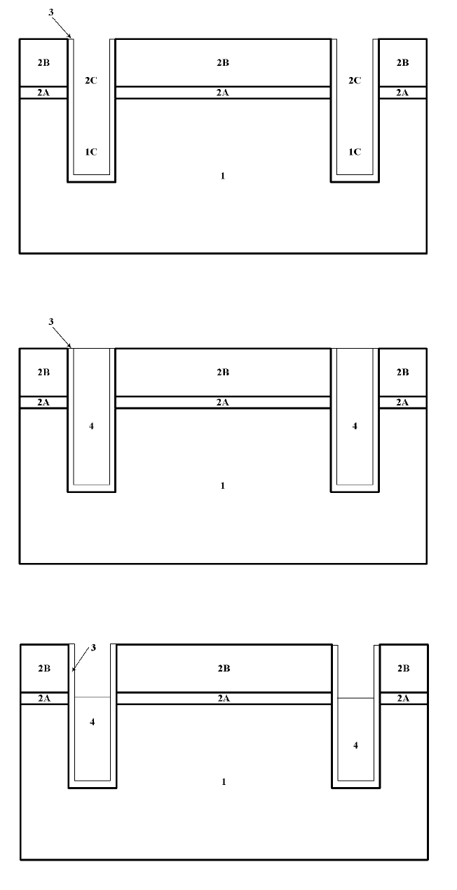

The various steps of the method for manufacturing the device according to the present invention will be described in detail below with reference to the schematic cross-sectional views of FIGS. 1-6.

Referring to FIG. 1, a hard mask layer 2 is formed on a substrate 1. The hard mask layer 2 and the substrate 1 are photoetched/etched to form a shallow trench. A liner 3 is deposited in the shallow trench.

The substrate 1 may be provided and appropriately selected according to the requirements for the application of the device. The material used as the substrate 1 may comprise one of monocrystal silicon (Si), Silicon On Insulator (SOI), monocrystal germanium (Ge), Germanium On Insulator (GeOI), strained silicon (strained Si), silicon germanium (SiGe), compound semiconductor materials, such as gallium nitride (GaN), gallium arsenide (GaAs), indium phosphide (InP), and indium antimonide (InSb), and carbon-based semiconductor, such as graphene, SiC, and carbon nanotube, etc. Preferably, the substrate 1 may be bulk silicon, e.g. a Si wafer, and SOI, so as to be compatible with the CMOS technology to apply to a digital logic integrated circuit.

The hard mask layer 2 is deposited on the substrate 1 and is photoetched/etched to form a hard mask layer pattern having an opening that expose a part of the substrate 1. The hard mask layer may be a single layer or multi-layer. Preferably, the hard mask layer includes at least a first hard mask layer 2A of oxide, e.g. silicon oxide, and a second hard mask layer 2B of nitride, e.g. silicon nitride, or oxynitride, e.g. silicon oxynitride. By using such stacked hard mask layer, the precision of the etched pattern can be well controlled, and the surface of the substrate to be etched and covered by the stacked hard mask layer can be well protected. A photoresist (not shown) is spin coated and is exposed and developed to form a photoresist pattern. A hard mask layer opening 2C is formed by performing anisotropic etching in the hard mask layer 2A/2B by means of dry etching, such as plasma etching, using the photoresist pattern as a mask, until the substrate 1 is exposed. At this time, the surface of the substrate 1 is not over-etched due to the stacked structure of the hard mask layer, so the defect density of the surface is not increased. Although the opening 2C is shown as two sections in the cross-sectional view, it actually surrounds the active region of the device, namely, it is of a ring-shaped structure in the top view (not shown), for example, a rectangular ring frame.

The part of substrate 1 exposed in the opening is etched using the hard mask layer pattern as a mask until reaching a certain depth H under the surface of the substrate 1. Preferably, the substrate 1 may be etched in an anisotropic manner by means of dry etching. When the material of the substrate 1 is Si, a solution having good anisotropy used for wet etching, such as TMAH, may also be used for the etching. As shown in FIG. 1, an opening 1C is also formed in the substrate 1 so as to form a shallow trench. The opening 1C has the same width W as the opening 2C. The depth H of the opening 1C of the substrate 1 that is from the top surface of the substrate 1 to the bottom surface of the opening 1C is smaller than the thickness of the substrate 1. For example, the depth H of the opening 1C is smaller than or equal to about ⅔ of the thickness of the substrate 1, depending on the specific requirements for the insulation property of the device. The width W of the openings 1C and 2C (shallow trench) is smaller than the depth H thereof. For example, the width W is only about ⅕-⅓ of the depth H.

Preferably, the liner 3 may be deposited in the shallow trench by means of a conventional depositing method, such as LPCVD, PECVD, HDPCVD, and ALD, etc., so as to eliminate defects on the surface of the shallow trench in the substrate, to limit the volume expansion of the STI to be formed later and to prevent damage to the substrate caused by the subsequent ion implantation. The material used as the liner 3 may be preferably different from both the material of the substrate 1 and the insulating material of the STI to be formed later. As an example, when the material of the substrate 1 is Si and the material of the STI to be formed later is silicon oxide, the material of the liner 3 is a nitride, e.g., silicon nitride, or oxynitride, e.g., silicon oxynitride. Preferably, the liner 3 may comprise a laminated structure which includes at least a first liner of oxide and a second liner of nitride, while the first and second liners are not individually shown in the figures. The total thickness of the liner is, for example, about 5-10 nm.

Referring to FIG. 2, a shallow trench filling layer 4 is formed in the shallow trench. The shallow trench filling layer 4 is deposited in the shallow trench (the opening 1C) and the opening 2C using a conventional depositing method, such as LPCVD, PECVD, HDPCVD, and ALD. The material of the shallow trench filling layer 4 is chosen to be the same as that of the substrate 1, such as a silicon based material including one of polysilicon, amorphous silicon, and microcrystal silicon. Then, the shallow trench filling layer 4 is planarized by CMP until the hard mask layer 2, e.g. the upper second hard mask layer 2B, is exposed.

Referring to FIG. 3, the shallow trench filling layer 4 is etched, so that the upper surface of the shallow trench filling layer 4 is lower than the hard mask layer 2 and higher than the substrate 1. In the case that the material of the shallow trench filling layer 4 is Si, the shallow trench filling layer 4 may be etched back by means of plasma dry etching or wet etching using TMAH, so that the upper surface of the shallow trench filling layer 4 is lower than the upper surface of the second hard mask layer 2B, preferably lower than the upper surface of the first hard mask layer 2A, and preferably the upper surface of the shallow trench filling layer 4 is higher than the upper surface of the substrate 1. Such an etching depth is selected to control the amount of the remainder of the shallow trench filling layer 4, thereby controlling the magnitude of the generated stress during the subsequent formation of the STI.

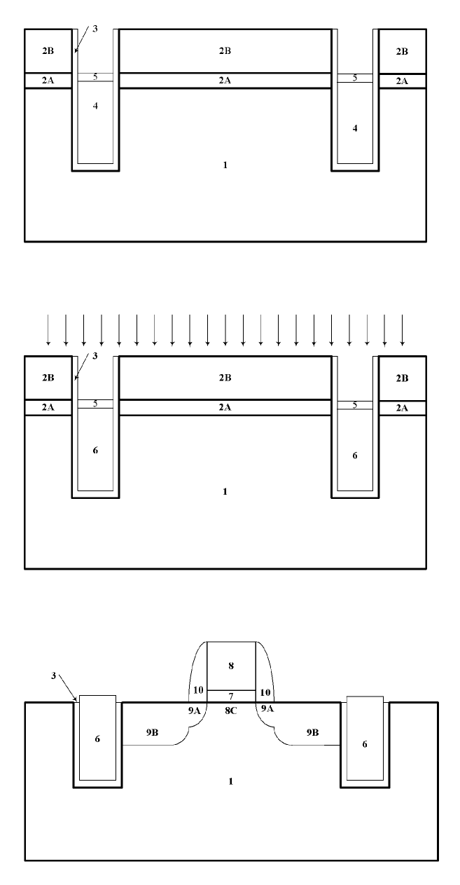

Referring to FIG. 4, a cap layer 5 is formed on the upper surface of the remaining shallow trench filling layer 4. For example, the cap layer 5 is deposited using a conventional depositing method, such as LPCVD, PECVD, HDPCVD, and ALD. Preferably, the material of the cap layer 5 may be the same as the material of the liner 3. Preferably, a harder material, for example, nitrides or oxynitrides, may be used as the material of both the cap layer 5 and the liner 3. Preferably, the thickness of the cap layer 5 may be about 10-20 nm, so that the extent of expansion can be controlled during the subsequent formation of the STI, thereby controlling the magnitude of the stress. The upper surface of the cap layer 5 is not necessarily flush with the upper surface of the first hard mask layer 2A as shown in FIG. 4, but may fluctuate near the interface between the first and second hard mask layers, for example, with about ±5 nm.

Referring to FIG. 5, ions are implanted into the shallow trench filling layer 4 and an annealing is performed, so that the shallow trench filling layer 4 of semiconductor is transformed into a shallow trench isolation (STI) 6 of insulator. The implanted ions are selected according to the requirements for the material of the shallow trench isolation 6. For example, when oxygen ions are implanted, O reacts with Si in the shallow trench filling layer 4 to form the shallow trench isolation 6 of silicon oxide. In the process of Si being transformed into SiO₂, the volume expansion is more than about 50%. However, the expansion of SiO₂ leads to an enormous compressive stress, for example, greater than about 1 GPa, and preferably between about 2 to 4 GPa, in the STI 6 due to being blocked off by the upper harder cap layer 5, so that stresses are applied to the channel region and the carrier mobility is increased. The implanted ions at least mainly include O, for example, with an atomic percent being above 80%. In addition, the implanted ions include a small amount of other ions, such as N, C, F, B, and P, etc., so as to form other insulating materials, such as silicon oxynitride, silicon oxycarbide, fluorine-doped silicon oxide, BSG, and BPSG, etc. Even a metal element, such as Ti, Ta, and Hf, etc., may also be doped into the implanted ions so as to react with oxygen to form a material having a high dielectric constant, thereby improving the insulation performance of the STI at the same time. The (total) dose of the implanted ions is greater than or equal to about 10¹⁶ cm⁻², so that the extent of expansion of the STI 6 can be controlled and the compressive stress of the STI can be indirectly controlled. The annealing temperature is, for example, greater than or equal to about 900° C., and the annealing time is, for example, about 30 s-10 min. In addition, in order to further improve the device performance, for example, to prevent the implanted ions from diffusing into the active region, the liner 3 may be preferably deposited in the trench before depositing the shallow trench filling layer 4.

Referring to FIG. 6, the hard mask layer 2A/2B is removed, and a semiconductor device structure is formed in the active region surrounded by the STI 6. For example, the hard mask layer 2A/2B is removed by wet etching or dry etching A gate stack comprising a pad oxide layer (e.g. silicon oxide, not shown), a gate insulating layer 7 (e.g. high k material), a gate conductive layer 8 (e.g. doped polysilicon, metal, metal alloy, metal nitride) is formed on the surface of the active region of the substrate 1 surrounded by the STI 6 by performing deposition and etching on the surface of the active region. A first ion implantation is performed on a source and drain using the gate stack as a mask to form lightly doped source and drain extension regions 9A. Gate spacers 10 made of silicon nitride are formed on the substrate 1 on both sides of the gate stack. A second ion implantation is performed on the source and drain using the gate spacers 10 as a mask to form heavily doped source and drain regions 9B. A channel region 9C is composed of a part of the substrate 1 between the source and drain regions 9A/9B. A self-alignment process is performed using a silicide on the source and drain regions 9B to form a metal silicide (not shown) so as to reduce the source and drain resistances. An interlayer dielectric layer (not shown) that is formed from a low-k material, such as silicon oxide, is formed on the entire device. The interlayer dielectric layer is etched to form a contact hole that directly reaches the metal silicide. The contact hole is filled with a metal to form a contact plug (not shown).

In the method for manufacturing the semiconductor device according to the present invention, an insulating material is formed by implanting ions into the filling material in the shallow trench, and a compressive stress is applied to the active region of the substrate due to the volume expansion of the filling material, so that the carrier mobility in the channel regions to be formed later can be increased and the device performance can be improved.

Although the present invention has been illustrated with reference to one or more exemplary embodiments, it shall be understood by those ordinary skilled in the art that various appropriate changes and equivalents can be made to the device structure without departing from the scope of the present invention. In addition, many modifications that might be adapted to specific situations or materials can be made from the teaching disclosed by the present invention without departing from the scope thereof. Therefore, the present invention is not intended to be limited to the specific embodiments which are disclosed as preferred implementations to carry out the invention, but the disclosed device structure and the method for manufacturing the same will include all embodiments that fall into the scope of the present invention.

1. A method for manufacturing a semiconductor device, comprising:
forming a shallow trench in a substrate;
forming a shallow trench filling layer in the shallow trench;
forming a cap layer on the shallow trench filling layer; and
implanting ions into the shallow trench filling layer and performing an annealing to form a shallow trench isolation.

2. The method for manufacturing a semiconductor device according to claim 1, wherein after forming the shallow trench and before forming the shallow trench filling layer, the method further comprises forming a liner in the shallow trench.

3. The method for manufacturing a semiconductor device according to claim 1, wherein forming the shallow trench further comprises:
forming a hard mask layer on the substrate;
photoetching/etching the hard mask layer to form a hard mask layer pattern which has a plurality of openings exposing the substrate; and
etching the substrate exposed in the openings to form the shallow trench.

4. The method for manufacturing a semiconductor device according to claim 3, wherein forming the shallow trench filling layer further comprises:
depositing a shallow trench filling layer in the shallow trench;
planarizing the shallow trench filling layer to expose the hard mask layer; and
etching the shallow trench filling layer so that the upper surface of the shallow trench filling layer is lower than the upper surface of the hard mask layer.

5. The method for manufacturing a semiconductor device according to claim 4, wherein the hard mask layer includes at least a first hard mask layer and a second hard mask layer, and the shallow trench filling layer is etched so that the upper surface of the shallow trench filling layer is lower than the upper surface of the first hard mask layer.

6. The method for manufacturing a semiconductor device according to claim 1, wherein the liner and/or the cap layer comprise one of nitrides and oxynitrides.

7. The method for manufacturing a semiconductor device according to claim 1, wherein the thickness of the cap layer is about 10-20 nm.

8. The method for manufacturing a semiconductor device according to claim 1, wherein the implanted ions include at least oxygen.

9. The method for manufacturing a semiconductor device according to claim 8, wherein the implanted ions further include one of N, C, F, B, P, Ti, Ta, and Hf.

10. The method for manufacturing a semiconductor device according to claim 1, wherein the dose of the implanted ions is greater than or equal to about 10¹⁶ cm⁻².

11. The method for manufacturing a semiconductor device according to claim 1, wherein the shallow trench filling layer comprises one of polysilicon, amorphous silicon, and microcrystal silicon.

12. The method for manufacturing a semiconductor device according to claim 2, wherein the liner and/or the cap layer comprise one of nitrides and oxynitrides.
